(19) United States
(12) Patent Application Publication
(10) Pub. No.: US 2021/0143773 A1
(43) Pub. Date: May 13, 2021

(54) Low Specific Mass Space Power System

(71) Applicants: Todd Fillmore Sheerin, Beverly Hills, CA (US); Abraham Loeb, Lexington, MA (US)

(72) Inventors: Todd Fillmore Sheerin, Beverly Hills, CA (US); Abraham Loeb, Lexington, MA (US)

(21) Appl. No.: 16/988,674

(22) Filed: Aug. 9, 2020

Related U.S. Application Data
(60) Provisional application No. 62/885,870, filed on Aug. 13, 2019.

(51) Int. Cl. H02S 40/22; G02B 5/22; G02B 5/26

(52) U.S. Cl. CPC H02S 40/22; G02B 5/26; G02B 5/22

(57) ABSTRACT

Aspects of the disclosure are directed to generating solar power. In accordance with one aspect, an apparatus includes a concentrator with an optical filter that concentrates a filtered light and passively radiates a rejected light, and a photovoltaic (PV) conversion system which includes photovoltaic (PV) cells that are spectrally matched to the filtered light.

### CLAIM OF PRIORITY UNDER 35 U.S.C. § 119

The present application for patent claims priority to Provisional Application No. 62/885,870 entitled “Low Specific Mass Space Power System”, filed Aug. 13, 2019, and assigned to the assignee hereof and hereby expressly incorporated by reference herein.

### TECHNICAL FIELD

This disclosure relates generally to the field of space power system, and, in particular, to low specific mass space power system.

### BACKGROUND

Space missions use a space platform to host a mission payload to achieve mission goals. Space platform performance is limited by energy generation capability, available mass and thermal dissipation capability. Space platforms typically use solar photovoltaic cells to convert solar radiative electromagnetic energy into electric energy to serve as the primary power source for the space platform. However, solar radiative energy flux diminishes as the square of the distance from the sun, so many space missions may not have enough energy using traditional methods. In addition, the mass of the platform power source may be severely limited by the launch mass capabilities of current launch vehicles. There is a need for highly mass-efficient solar photovoltaic power systems for space platforms to accomplish desired space mission goals.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides apparatus and method for generating solar power. Accordingly, an apparatus including a concentrator, wherein the concentrator includes an optical filter and wherein the optical filter includes a first characteristic of concentrating a filtered light and a second characteristic of passively radiating a rejected light; a photovoltaic (PV) conversion system coupled to the concentrator, wherein the photovoltaic (PV) conversion system includes a plurality of photovoltaic (PV) cells, wherein a majority quantity of the plurality of photovoltaic (PV) cells is spectrally matched to the filtered light.

In one example, the optical filter includes a single spectral window. In one example, the single spectral window reflects or transmits the filtered light. In one example, the single spectral window transmits, absorbs, or reflects the rejected light. In one example, the optical filter is a reflectance/transmittance (R/T) filter. In one example, the optical filter is a transmittance/absorbance (T/A) filter. In one example, the optical filter is a transmittance/reflectance (T/R) filter. In one example, the concentrator is a concave reflector (CR). In one example, the concentrator is a light-channel (LC). In one example, the concentrator comprises a low areal mass density deployable structure.

Another aspect of the disclosure provides a method for solar power generation, the method including filtering a light to generate a filtered light and a rejected light; concentrating the filtered light; and passively radiating the rejected light. In one example, the method further includes concentrating the filtered light to a plurality of photovoltaic (PV) cells. In one example, the concentrating step includes reflecting the filtered light. In one example, the concentrating step includes transmitting the filtered light. In one example, the passively radiating step includes transmitting the rejected light. In one example, the passively radiating step includes absorbing the rejected light. In one example, the passively radiating step includes reflecting the rejected light. In one example, the method further includes generating solar power using the plurality of photovoltaic (PV) cells.

These and other aspects of the present disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates two examples of low specific mass space power system in space configuration.

FIG. 2 illustrates an example of the low specific mass space power system with exemplary subsystems.

FIG. 3 illustrates an example of an optical filter design.

FIG. 4 illustrates an example of optical filters that may be applied to the concentrator subsystem of a low specific mass space power system.

FIG. 5 illustrates a set of example reflecting concentrators.

FIG. 6 illustrates an example of a transmitting concentrator design.

FIG. 7 illustrates a set of examples of common constituents of the low specific mass space power system.

FIG. 8 illustrates a set of examples for the physical geometry and deployment configurations of a low specific mass power system.

FIG. 9 illustrates an example of requirements of the combined power and propulsion system specific mass as a function of the transfer time from Earth orbit to Mars orbit.

FIGS. 10a and 10b illustrate example graphs of specific mass sensitivity for a low specific mass space power system near and far from Earth.

FIG. 11a illustrates example mission profiles for an interplanetary transfer from Earth to Mars enabled with a low specific mass space power system.

FIG. 11b illustrates example mission profiles for a low Earth orbit to geosynchronous orbit transfer enabled with a low specific mass space power system.

FIG. 12 illustrates a flow diagram for generating solar power.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

Space missions are deployed to achieve mission goals, such as communication, navigation, remote sensing, data collection, science exploration, weather monitoring, etc. Space missions may use a space platform, e.g., a satellite or spacecraft, to host a mission payload in support of the mission goals. In one example, the space power system may also be applied to terrestrial applications or to surface applications on other bodies in our Solar System or beyond. One important requirement for the hosting of the mission payload is providing an adequate source of electric energy on the space platform. The source is a space power system, for example, a solar power system. One important space power system is a solar photovoltaic system which employs photovoltaic cells to convert solar radiative energy to electric energy. Since the solar radiative energy has a broadband spectral distribution (i.e., the solar radiative energy is spread over a wide range of wavelengths), solar photovoltaic cells may be matched to the spectrum of the solar radiative energy for maximum energy conversion to electric energy. In one example, the maximum solar radiative energy flux is in the visible part of the electromagnetic spectrum, for example, from about 400 nm to 700 nm wavelength.

In one aspect, space missions have a need for the following example features: low mass, deep space power systems and low specific mass space power systems. In a first example regarding low mass: all space missions strive for mass reduction given the high costs associated with launch, and electric power availability is a critical driver for all types of space missions with higher power allowing greater mission opportunities.

In a second example regarding deep space power systems: conventional solar power systems have diminished utility at distances far away from the sun, while currently available alternative energy sources for deep space missions such as radioisotope thermal generators (RTGs) and nuclear reactors are heavy, costly, and complex.

In a third example regarding low specific mass space power systems: a lightweight power system enables several missions (e.g., data collection, communication, instrument operations, etc.) as well as transformative application of electric propulsion. A critical parameter for a power-limited propulsion system (e.g., an electric propulsion system) is the specific mass, or mass per unit power, of the combined power and propulsion system. In one example, the inverse relation, power per unit mass, which is referred to as specific power, is also defined as an interchangeable figure of merit for space power systems. An equivalent description for a low specific mass space power system is a high specific power space power system. While electric propulsion thrusters are being developed with low specific mass, there are currently no power systems with low specific mass to be used with these thrusters to realize rapid interplanetary missions.

In one example, the low specific mass space power system increases the power production capabilities of photovoltaic (PV) cells by filtering and concentrating sunlight to improve PV junction efficiency and to increase the total power output of a fixed mass of photovoltaic cells. FIG. 1 illustrates two examples 110, 120 of low specific mass space power system in space configuration. In FIG. 1, example 110 depicts a configuration example where PV cells are integrated with the concentrator in a narrow, linear geometry. In FIG. 1, example 120 depicts a configuration where sunlight is concentrated onto a small area of PV cells located near the spacecraft. A design feature which enables a low specific mass is the use of a low areal mass density system, or a system with low mass per unit area, for sunlight spectral filtering, concentration, and excess heat removal. In addition, the PV cells are illuminated with narrowband light to maximize the power output per unit mass of the PV cells without requiring dedicated or extensive radiators or active cooling, for example.

In one example, the low specific mass space power system may include two primary subsystems: a concentrator and a photovoltaic energy conversion system. These subsystems may be implemented as a single monolithic structure, or multiple modular constituents that may be combined. In one example, the concentrator may include a low areal mass density deployable structure that may include a substrate coated with an optical filter and support constituent structures used to deploy, shape, and orient the concentrator with respect to the photovoltaic energy system and the Sun. In one example control of deployment, shape geometry, or relative orientation is actuated with active or passive feedback control with mechanized components, shape memory alloys, piezoelectric motors, other motor varieties, or structural or electronic elements that respond light or heat stimuli and modifying shape, angle, or orientation of concentrator surfaces or support structures. The concentrator controls the narrowband optical intensity (in watts per meter) at the PV cells by concentrating and thereby increasing the incident optical intensity of filtered light at the PV cells to maximize PV efficiency and power production while allowing for passive cooling at the PV cells, for example without additional or substantial dedicated radiators or active cooling mechanisms.

In one example, the concentrator may include one or more modules which may be individually or collectively deployed and controlled. Each module may include (a) a low areal mass substrate surface constituent to perform sunlight filtering and concentration, (b) structural constituents to facilitate high concentration efficiency and excess heat removal from the system, and/or (c) a passive or active control constituent to deploy, position and orient the reflective surface with respect to the sun, the PV cells and other modules.

In one example, the concentrator may include an optical filter, for example a notch reflection filter, a long-pass filter, a short-pass filter, a dichroic filter, or a band-pass filter, to implement one or more spectral windows. A single spectral window is a contiguous range of wavelengths which allow energy transfer. In one example, the concentrator may include a thin-film material similar to solar sail materials for the reflective filtering and concentration surface substrate. The concentrator may also include a thin-film optical coating commonly used in the optics and laser field that is selected or designed to match corresponding photovoltaic junctions of the PV cells. Depending on the emissivity properties of the surface material selected, a high emissivity coating may be used on the non-reflective or non-transmitting concentrator surface features to enhance residual solar energy dissipation away from the space platform, for example from the PV cells.

In one example, designs may include methods and processes to manufacture large areas of coated thin-film material and methods to ensure the coating quality throughout the lifecycle from production, through launch and deployment, and onto flight operations. Design and methods of operations for deployable structural and control constituents may ensure overall low specific mass and high system efficiency with the potential for lower areal mass density or improved optical filter performance with the use of a metamaterial for the concentrator surface. In one example, the use of nanostructured substrates acting as photonic crystals allows the substrate to function as an optical filter or concentrator waveguide, or a combination thereof.

FIG. 2 illustrates an example 200 of the low specific mass space power system with exemplary subsystems. In the example in FIG. 2, the reflective surface of the concentrator facing the photovoltaic energy conversion system is treated to act as an optical filter, for example a notch filter, a long-pass filter, a short-pass filter, a dichroic filter, or a band-pass filter, either with thin-film coating or with a metamaterial or photonic crystal surface. The optical filter, for example, reflects a narrow frequency band of sunlight onto matched PV junctions of the PV cells and transmits or absorbs the remaining solar spectrum to be passively re-emitted away from the PV system. In one example, the narrow frequency band is a single spectral window. For example, excess solar energy (i.e., energy outside of the narrow frequency band) that is transmitted through the filter and a transparent concentrator substrate or absorbed by the concentrator substrate or optical filter to be passively radiated from the system, facilitated by the large surface area of the concentrator structure and either a thin-film high emissivity coating, the bare structure, or a high emissivity metamaterial or photonic crystal finish on the opposing, non-reflective side of constituents of the concentrator, for example those that are not transparent.

In the example depicted in FIG. 2, the space power system may be deployed on-orbit, where a thin-film, transparent substrate, for example a polyimide like colorless polyimide 1 (CP1), is deployed into a linear parabolic dish shape, for example a parabolic trough, with focus line formed on a strip of PV cells connected as a PV array. In one example, transparent Mylar film or other transparent plastics are used for the concentrator substrate material. Lightweight structural constituents, for example bi-stable, spring-like, mesh-like, or foldable composites, plastics, or metallic structures, may provide a shape for the concentrator substrate by deploying into rigid parabolas at regular intervals along the substrate sheet, with bi-stable, spring-like, mesh-like, jointed, stiff, or extendable booms connecting these parabolas to the PV array strip. One example involves mechanized concentrator structures and booms for deployment or orientation. The transparent thin-film substrate sheet spanning the parabolic support constituents is coated with an optical filter, for example, with a notch filter or a long-pass filter that, for example, reflects solar spectra that are matched to preferred wavelengths at the PV's single-junction or multi junction PV cells, and transmits the remainder of the solar spectrum that would otherwise contribute to waste heat in the system. In the example, FIG. 2 shows the deployment geometry as well as two cross-section views depicting the concentrator subsystem at a location that is not directly supported by structural constituents, and at a second location that is directly supported by structural constituents.

In one example, as shown in FIG. 2, the photovoltaic energy conversion system includes PV junctions which match the spectral characteristics of the optical filter in the concentrator. For example, usage of multiple PV junctions with a plurality of frequency bands may enable greater utilization of the solar spectrum. In one example, this multi-spectral feature may add design complexity (by usage of multiple PV junctions and additional concentrator mass or complexity to accommodate wider or multiple frequency bands in the optical filter). In one example, a single spectral window from the plurality of frequency bands may be used. In other examples, two or more spectral windows may be used.

In one example, FIG. 3 illustrates an example of an optical filter design 300. The optical filter design 300, in one example, is for a single spectral window between 450 nm and 600 nm wavelength in which a notch filter is used to reflect desired wavelengths (i.e., filtered light) and transmit or absorb the remainder of the incident solar spectrum (i.e., rejected light). In one example, a majority quantity of the plurality of PV cells is spectrally matched to the filtered light. The first graph 310 shows a blackbody spectrum of the sun with the spectral window of desired sunlight wavelengths shown in bold. The second graph 320 shows a concentrator reflective notch filter with 90% reflectivity within the spectral window. The third graph 330 shows an external quantum efficiency (EQE) plot for a matched PV junction for high efficiency conversion of the reflected frequency band at the PV cell depicted with 95% EQE in the spectral window.

Single-junction photovoltaics based on indium gallium phosphide (InGaP), for example, exhibit high conversion efficiencies, or external quantum efficiencies, in the 400 nm-650 nm wavelength range, while gallium arsenide (GaAs) single junction photovoltaics exhibit high external quantum efficiencies in the 500 nm-800 nm wavelength range, for example. Dual junction or multi junction cells based on InGaP, GaAs, or other semiconductors like GaInAsP and GaInAs provide alternative options. PV architectures, thin-film PV cells or future PV architectures may be employed to integrate PV junctions and cells into arrays for a low specific mass space power system to reduce overall specific mass with improved efficiency and/or reduced mass. Articulation of the PV cells with respect to the sun, the host spacecraft and the concentrator may be accomplished with static or dynamic, passive or active means, but may be selected for a specific mission to ensure low specific mass and to meet minimum power requirements throughout mission life. One example implementation involves a fixed configuration in which the photovoltaics are held at a constant orientation with respect to the concentrator after deployment, with the entire solar power system gimbaled in one or more axes to face the sun for operations.

FIG. 4 illustrates an example 400 of optical filters that may be applied to the concentrator subsystem of a low specific mass space power system. The solar spectrum 410 of incident sunlight is shown to the left in FIG. 4 with spectral radiance (in units of kW/sr/m²/nm) as a function of wavelength. Optical filters that reflect desirable wavelengths to the PV system and allow other wavelengths to transmit through them are referred to as reflectance/transmittance (R/T) filters. Two examples of R/T filters are reflective notch filters or reflective long-pass filters, with illustrations 420 shown in FIG. 4. Optical filters that instead transmit desirable wavelengths either directly to the PV system or to an underlying reflective opaque concentrator surface and absorb the remainder of the solar spectrum are referred to as transmittance/absorbance (T/A) filters, for transmitting/absorbing. Filters that transmit desired wavelengths and reflect the remainder of the solar spectrum are referred to as transmittance/reflectance (T/R) filters, for transmitting/reflecting. Examples of T/A and T/R filters, with illustrations 430 shown in FIG. 4, are band-pass and short-pass filter types. In one example, optical filter spectral properties are selected or varied across the concentrator surface according to the angle of incidence expected for sunlight during nominal operations of the concentrator system. Examples of variations include wavelength-shifted filter properties or varying thickness of optical filter layering to accommodate the incidence angle. In one example, one type of optical filter, for example a notch, edge, band-pass, long-pass, or short-pass, that is designed for small incidence angles, for example zero degrees, is used for concentrator surface area that nominally reflects or transmits filtered light at small angles. In one example, another type of optical filter designed to function at large angles of incidence, for example a dichroic filtered designed in notch, edge, band-pass, long-pass, or short-pass configurations, is used for concentrator surface area that nominally reflects or transmits filtered light at large angles to the PV system. In one example, the wavelength-shifting property of dichroic filters when exposed to varying incident light angles is used to design different dichroic filter implementations for different regions of the concentrator surface, such that each filter and each incidence angle results in a spectrally-matched window of reflected or transmitted filtered light concentrated on the photovoltaic cells. In one example, multiple different optical filter types are used in the same concentrator system, applied to the concentrator substrate such that the optical filter at each location on the concentrator is designed to filter and concentrate a matching spectral window onto the PV cells according to the nominal incidence angle of sunlight at that location for nominal operations.

FIG. 5 illustrates a set 500 of example reflecting concentrators. Examples architectures shown in FIG. 5 are a concave reflector (CR) and a light-channel (LC). In a CR geometry, the concentrator reflects incident sunlight onto a focus point or a focus line—an example of this is a parabolic dish or parabolic trough. In an LC geometry, incoming sunlight is redirected with one or more reflections down a light-channel or light-tube to reach a focus point or focus line or focus ring. In both CR and LC configurations, a large area of incident sunlight is concentrated onto a smaller area PV for conversion. And in both the CR and LC configurations, the concentrator surface acts also as a sunlight spectral filter and excess heat removal system. In one example, the photovoltaic system also includes an optical filter, for example a T/R filter, to transmit properly filtered light to the PV cells and reflect unwanted solar wavelengths that were not filtered.

FIG. 5 also illustrates three example options for concentrator substrate and optical filter combinations: Option 1, corresponding to CR.1 and LC.1, includes a transparent substrate with an R/T optical filter, reflecting desired solar wavelengths and transmitting remaining sunlight. Option 2 includes an opaque, absorptive substrate that absorbs transmitted solar wavelengths through an R/T filter, re-emitting absorbed energy on the opposite side of the substrate, for example with an emissive coating. Option 3 includes an opaque, reflective substrate with a T/A optical filter transmitting desired solar wavelengths to be reflected off the substrate, with remaining wavelengths absorbed in the filter and converted to heat, which is then transferred with conduction or radiation through the concentrator substrate to be emitted at a high emissivity surface facing away from the PV system. In one example involving any of the Options 1, 2, or 3, the substrate shape or relative geometry varies along the concentrator surface with notches or variably-angled structural elements, for example, to accommodate for varying sunlight angles of incidence along the concentrator surface to improve the function of optical filters operating at angles necessary for concentration.

Concerning Option 1 (CR.1 and LC.1) implementation example shown in FIG. 5, an example of the reflector is one that includes a transparent substrate with a notch reflector filter coating or a long-pass filter coating that reflects selected solar spectra back to the photovoltaics while transmitting the remainder of the solar spectrum. In this example, the concentrator substrate may be a thin-film material like a transparent polyimide, for example CP1 or Kapton, which have extensive spaceflight heritage and are produced in highly transparent forms. CP1 is often coated and used for solar sail applications, generally with a reflective material, but which would instead in this instance be coated with an R/T filter as described in FIG. 4. In one example, another plastic material or Mylar is used as the concentrator substrate.

One example of an optical notch filter for application to any example low specific mass space power system is a dichroic reflector film that reflects sunlight with wavelengths between 450 nm-600 nm, while transmitting other wavelengths in the solar spectrum. Another example is a polychroic reflector that reflects sunlight in multiple spectral bands, for instance wavelengths between 450 nm-600 nm and between 700 nm-850 nm while transmitting the rest. In one example, a long-pass filter designed to transmit all wavelengths longer than a given value and reflect the rest of the solar spectrum is used, since much of the unused solar spectrum is in the long wavelengths. A variety of commercial off-the-shelf optical filters may be used to achieve solar spectrum filtering. In one example, several different optical filters are used to coat a single concentrator, with different optical filters selected with spectral properties according to the sunlight incidence angle with respect to concentrator surface so that resulting optical filtering and concentration occurs with high efficiency and produces spectral windows matching the PV system photovoltaic cells.

These examples of wavelength ranges are given as examples to match PV junction spectral ranges, though for specific implementations, the spectral range of the optical filter may be selected in conjunction with the PV system's photovoltaic junctions. In one example a broad range of optical filters may be used. Many options are available to deposit such films, including R/T, T/A, or TR filters, to a variety of substrate materials that include plastics, polyimides, and other transparent, thin-film media relevant to this example. Deposition options include, for example, ion-beam sputtering, laminating, dyeing, hot-rolling, or direct-depositing. In one example, the substrate is designed with nanostructures or with metamaterials to perform desired optical filtering without the need for additional optical filter coating.

Concerning Option 2 (CR.2 and LC.2) implementation examples shown in FIG. 5, the concentrator surface facing the PV cells is absorptive across the solar spectrum, and a thin film of optical coating is applied to the side of the concentrator that faces the PV cells, or in the case of LC.2 on both sides of the louver-like structures and only on the PV-facing side of the concentrator back-plane. The R/T optical coating in these examples acts as a wavelength filter to reflect only the narrowband spectrum useful for conversion at PV cells, allowing the rest of the solar spectrum to be transmitted to the absorptive substrate surface or to be absorbed by the optical filter. The concentrator surface may be absorptive, for example, by the material selection or with application of an absorptive film or with surface roughening or other treatments. The solar spectrum energy that is not reflected is converted into thermal energy within the structure of the concentrator by means of absorption and thermal conduction within the concentrator. This additional thermal energy is subsequently re-radiated away from the PV cells for example by means of a thermally conductive path in the concentrator structure from the PV-facing side through the cross section of the concentrator structure to the opposite side, which may be treated for example with a high emissivity coating for rejection of this absorbed thermal energy, as shown in Option 2 of FIG. 5.

One example of a thermally conductive path is the selection of a concentrator surface material that has high thermal conductivity. Another example involves the use of dedicated thermal conduction pathways built into the concentrator surface, for example, as webbing in the surface constituents or, for example, as a secondary function for the structural constituents or deployment constituents necessary to maintain the shape and orientation of the concentrator surfaces. Emission may take place, for example, across the entire opposite surface of the concentrator away from PV cells that is treated for example with high emissivity coating or other means to ensure a higher emissivity than the surface facing PV cells. In another example, emission of the absorbed thermal energy takes place at isolated thermal emission locations that are facing away from PV cells and that are designed to be more highly emissive than any other feature of the concentrator, for example, with material or coating selections. These isolated emission locations may, for example, be connected with thermally conductive pathways to the absorptive surface constituents receiving excess sunlight.

Concerning Option 3 (CR.3 and LC.3) implementation examples shown in FIG. 5, another example of the low specific mass space power system involves a concentrator surface that is opaque and reflective, instead of opaque and absorptive, across the solar spectrum on the surface that faces PV cells. In this example, a T/A optical coating is applied to the concentrator surface allows for only a narrow band of sunlight to transmit through the filter to be reflected and concentrated on the PV system, with the remaining sunlight wavelengths blocked, and absorbed at the optical filter. The absorbed thermal energy at the optical filter of the Option 3 T/A filter conducts this thermal energy to the thermally-contacted substrate material, which then may radiate the excess heat away from the system at high emissivity locations or surfaces at the opposing side of the concentrator, i.e. away from PV cells.

For both Options 2 and Option 3 shown in FIG. 5, another example of thermal management of absorbed energy involves the use of discrete locations of the concentrator surface that are designed to act as thermal conduits to transfer absorbed thermal energy to highly emissive locations on the opposite surface of the concentrator, or to the emissive surfaces facing away from PV cells by means of thermally conductive pathways built into the concentrator. In another example, these structures may extend through the concentrator structure and act as the highly emissive locations themselves with surface treatment on the opposing side to ensure high emissivity directed away from PV cells.

FIG. 6 illustrates an example 600 of a transmitting concentrator design. In the example 600, the transmitting concentrator design includes a thin-film or low mass lens constituent or metamaterial that focuses incoming light onto a PV system. A T/R optical filter coating the sun-facing side of the lens transmits desirable wavelengths to be concentrated and rejects other wavelengths either with reflection or absorption of the remaining solar spectrum. An example of such a system is the combination of a thin-film Fresnel lens and a band-pass filter or a short-pass filter. In one example, the Fresnel lens may be manufactured from various materials including polymethyl methacrylate (PMMA), polyethylene terephthalate (PET), or polycarbonate (PC). As with the other configuration options, thin-film lens examples may be implemented as many individual lens modules or as large monolithic modules. One example includes many small thin-film lenses arranged in parallel or in an array, designed to each deploy with a corresponding small photovoltaic array extended along the optical range of each lens by means of a lightweight boom to a fixed focus position. In one example, the filtering and concentrating lens concentrates filtered light to a point or area. In one example, the filtering and concentrating lens concentrates filtered light to a line.

FIG. 7 illustrates a set 700 of examples of common constituents of the low specific mass space power system. The top of FIG. 7 shows a two-example option 710 for photovoltaic system implementations. Shown in the two-example option 710 is a first photovoltaic system, PV.1 which shows PV cells facing away from incident sunlight, with a reflective film coating on the module surface facing the sunlight. Additional reflective structures, for example reflective film mounted on mesh or another support structure, may extend, for example, from the PV cells to help direct filtered and concentrated light onto the active PV cell constituents in the case of imperfect steering from the concentrator. Also shown in the two-example option 710 is a second photovoltaic system, PV.2. The second photovoltaic system, PV.2, shows another implementation in which the sun-facing side of the PV system has an angled, cone or triangular prism-shaped reflective film to direct incoming light away from the back of the PV system to the concentrator area or away from the system entirely. As in PV.1, PV.2 shows the option to have additional reflective structures or films surrounding the PV cell active surface to help re-direct mis-directed filtered light from the concentrator onto PV junction(s). In one example that may be applied to either implementation of 710, an optical filter is applied to the photovoltaic cell surface to filter incoming light. In one example, radiator structures are mounted to the photovoltaic cell base or photovoltaic array base to help dissipate waste heat.

In the example shown in the middle of FIG. 7 are structural constituent (SC) examples 720. The structural constituent (SC) examples 720 shows a first structural constituent, SC.1, which is an example for an opaque structural constituent designed to absorb waste heat on the PV-facing side, for example with a high absorptivity, low emissivity coating, transmit absorbed heat by means of a thermally-conducting substrate material, and/or re-emit heat via a high emissivity surface coating away from the PV system. Also shown in the structural constituent (SC) examples 720 is a second structural constituent, SC.2. The second structural constituent, SC.2, shows a structural constituent designed to reflect the solar spectrum, thereby rejecting any waste heat from being absorbed into the system. In one aspect, this is accomplished, for example, by coating a composite structural constituent with a reflective film.

Examples of thermally-conductive substrates may include carbon fiber composites, composites with graphite including pyrolytic graphite, graphene, metallics, or other thermal conductors. Examples of high absorptivity, low emissivity materials that may be used on opaque constituents facing the PV system include plated nickel oxide metal, plated black chrome metal, plated black sulfide metal, Solchrome®, copper treated with NaCIO2 and NaOH, Thermafin®'s Black Crystal®, and galvanized metal. Examples of high emissivity materials for use in radiating away excess heat in directions that are not visible to the PV system may include white paints, light colored paints, zinc oxide with sodium silicate, magnesium oxide paint, magnesium/aluminum oxide paint, zinc orthotitanate with potassium silicate, anodized aluminum, potassium fluorotitanate white paint, white zinc oxide paint, titanium oxide white paint with methyl silicone, black paints, dark paints, strongly oxidized iron and steel, black silicates, black plastics, and blackening agents including, for example, graphite colloids. Examples of lightweight substrates may include composites that include carbon fiber composites, epoxied fabrics, or carbon fiber-reinforced plastics. And, examples of highly reflective surfaces may include aluminum coating, silver coating, or silvered or white paint.

In the example 730 at the bottom of FIG. 7, physical arrangements of optical filters and support constituents are shown, held together, for example, by low-outgassing epoxies or other glues. In one example, mounting with stitching or mechanical fixtures is used to hold together concentrator or PV system elements. Shape support to form the concentrator substrate into the concentrator geometry may be accomplished by epoxying the optically-coated concentrator substrate to an absorptive SC.1 constituent shaped in the geometry of the concentrator, for example, a parabolic trough as in the concave reflector (CR) examples of FIG. 5. In one example, the optically-coated concentrator substrate may be mechanically mounted to a structural support element with stitching, heat-treating, bonding, bolting, friction welding, or in manufacturing by producing the structural element as a protrusion or three-dimensionally printed element from the same or different material as the substrate. Concentrator shaping constituents may be physically connected to the PV system by means of an SC.2 constituent, for example, that forms a set of booms connecting the concentrator system to the PV system. In one example, boom constituents block the concentrator, and so they are designed, for example, to reject incident sunlight altogether to reduce the amount of absorbed light. One example of deployment involves spring-like elements or mechanisms, inflatable elements, or motorized or electrical elements that may include shape memory alloys, piezoelectric motors, or other motors. One example of a low mass structure to provide high stiffness and high accuracy surface geometry support includes mesh-like structures made from carbon fiber composites, metalics, plastics, fabric-based composites, or combinations thereof, for example plastics reinforced with carbon-fiber. One example includes mesh-like geometry resulting in structures that provide high stiffness and concentrating surface features with low mass.

A summary of the different basic examples of the low specific mass space power system is compiled in Table 1. A key design feature which enables a low specific mass is the use of low areal mass density material for sunlight concentration, filtering, and excess heat removal. In addition, in one example, the PV cells are illuminated with narrowband light to maximize the power output per unit mass of the PV cells without requiring active cooling. Table 1 illustrates a set of examples for a low specific mass space power system.

TABLE 1

| | Concentrator description | | | | | | |
|---|---|---|---|---|---|---|---|
| | | | | | | | Thin-film |
| | | | | | | | lens |
| | Concave reflector [CR] | | | Light-channel [LC] | | | [LENS] |
| | Cross-section geometry | | | | | | |
| | 200, 500 | | | 500 | | | 600 |
| Designation | CR.1 | CR.2 | CR.3 | LC.1 | LC.2 | LC.3 | LENS.1 |
| Concentrator | Transparent | Opaque, | Opaque, | Transparent | Opaque, | Opaque, | Transparent |
| substrate | | absorptive | reflective | | absorptive | reflective | |
| Concentrator | Reflect/transmit | Reflect/transmit | Transmit/absorb | Reflect/transmit | Reflect/transmit | Transmit/absorb | None |
| surface | optical filter | optical filter | optical filter | optical filter | optical filter | optical filter | |
| coating: | [R/T]: reflect | [R/T]: reflect | [T/A]: transmit | [R/T]: reflect | [R/T]: reflect | [T/A]: transmit | |
| viewing PV | desirable | desirable | desirable | desirable | desirable | desirable | |
| | spectrum, | spectrum, | spectrum | spectrum, | spectrum, | spectrum | |
| | transmit (or | transmit (or | and absorb waste | transmit (or | transmit (or | and absorb waste | |
| | absorb) waste | absorb) waste | | absorb) waste | absorb) waste | | |
| Concentrator | None | High emissivity | High emissivity | None | High emissivity | High emissivity | Transmit/reflect |
| surface | | material | material | | material | material | optical filter |
| coating: not | | | | | | | [T/R]: transmit |
| viewing PV | | | | | | | desirable |
| | | | | | | | spectrum |
| | | | | | | | and reflect waste |
| Primary | Transmission | Absorption | Absorption | Transmission | Absorption | Absorption | Reflection from |
| method of | through | (outside | (inside | through | (outside | (inside | concentrator |
| heat | concentrator | optical filter), | optical filter), | concentrator | optical filter), | optical filter), | |
| rejection at | | conduction, and | conduction, and | | conduction, and | conduction and | |
| concentrator | | emission | emission | | emission | emission | |

| | |
|---|---|
| PV cell | None; or Transmit/reflect [T/R] optical filter with desirable spectrum transmitted and waste reflected |
| surface | |
| coating: | |
| viewing | |
| concentrator | |
| PV surface | None; or High reflectivity and/or high emissivity material or radiator |
| coating or | |
| elements: | |
| not viewing | |
| concentrator | |

In one set of examples shown in Table 1, the low specific mass space power system includes two subsystems: a concentrator subsystem and a photovoltaic energy conversion system. In one example, the concentrator may include a low areal mass density deployable structure. The function of the concentrator is three-fold: spectral filtering of sunlight, concentration of selected solar spectra onto the photovoltaic energy conversion system, and rejection of excess energy and heat from the power system. The configuration of the concentrator may be, for example: a concave reflector (CR) as described in Table 1, FIG. 2, and FIG. 5; a light-tube or light-channel (LC) as described in Table 1 and FIG. 5; or a thin-film lens (LENS) as described in Table 1 and FIG. 6. An example of the optical design of the concentrator and PV system is shown in FIG. 3, with the action of several optical filter examples described in FIG. 4. Common constituents of the design examples given in Table 1 are shown in FIG. 7, including photovoltaic systems, structural constituents, and connection points in the system between structural constituents, concentrator substrates, and PV constituents.

In one example of the power system using a CR concentrator as shown in FIG. 5, the photovoltaic energy conversion system faces away from incident sunlight, with the concentrator subsystem acting as a spectral filter, directing only selected wavelengths back to the photovoltaic system. While the photovoltaic energy conversion centers, i.e., the PV cells, are facing away from the sun, the backside of the PV cells and any mechanical housing are exposed to incident broadband sunlight. Two methods to limit heating of the photovoltaics from incident sunlight are shown in FIG. 7 (PV.1 and PV.2). In PV.1, a reflective film on the sun-facing side of the photovoltaics (i.e. the backside of the photovoltaics) reflects away sunlight. In PV.2, reflective film is angled to direct incident sunlight away from the back of the PV and instead toward the concentrator structure to be filtered and re-directed back to the photovoltaic system, for example as shown in FIG. 5 CR.1 or CR.2. In one example, a radiator structure is used in place of the reflective structures to dissipate both waste heat from incident sunlight and waste heat from photovoltaic cells producing electricity with filtered incident light. In one example, the reflective structures depicted in FIG. 7 double as a radiator for the PV system and as a reflector to guide incident sunlight away from the backside of the PV cell.

In one aspect, all examples may be implemented at various scales, spanning designs that include a single large concentrator providing all the energy for the power supply system to designs that include many concentrator systems and many PV systems. Likewise, in one aspect, PV modules may be implemented in one example as a single array, or in another example as many arrays.

FIG. 8 illustrates examples for the physical geometry and deployment configurations of a low specific mass power system. The grouping 810 shows a set of geometry examples. Each example may be implemented alone or as one of many constituents that collectively provide power to the space platform. Some examples considered include folding or rolling stowing configurations, or fan-like deployment configurations. Further implementations include umbrella-like deployments or fern-like multi-roll configurations. Two-dimensional concentration options like a paraboloid (CR) concentrator with a point or area focus, a circular light-channel (LC) ring, and a circular thin-film (LENS) Fresnel lens with a point or area focus are considered, as well as one-dimensional concentration options, which include linear parabolic troughs (CR), strips of light-channels (LC), and linear Fresnel lenses (LENS) with linear focus regions.

The dashed box 820 shown at the bottom of FIG. 8 indicates an example of “fern-like” multi-roll deployment of a one-dimensional parabolic concave reflector. In this example, deployment may be accomplished by means of a long-axis roll-out deployment of a set of short-axis constituents that are rolled up along an orthogonal axis aligned with the “short-axis” labeled in the illustration. As the long-axis is deployed, the short axis is free to unroll as well. In this example, the coiled structures are, for example, SC.1 structures that are designed to be bi-stable in the stowed and deployed configuration, or designed to be in a high-energy state while stowed, and upon release, are allowed to relax to a lower energy state when fully deployed. In one example, the deployment of the long-axis unrolls a double-coiled structure with a spine consisting of a strip of photovoltaic cells connected in an array. Short-axis uncoiling then proceeds, where the composite SC.1 structures, for example, unfurl. When entirely unfurled, a bi-stable or spring-like boom structure, which may include SC.2 structures, for instance, begins attached both to the ends of the parabolic SC.1 structure and the PV system, and is allowed to reach a low-energy or stable state in a straight form, holding the PV strip a fixed distance from the parabolic concentrator shape. In one example, the connecting structures that hold the PV strip are folded or stowed straight and extend to the final shape once the other structures deploy. In the example of FIG. 8, the deployment sequence is shown from initial shape to final shape moving from top to bottom of the large dashed box 820. In another example, the actuation from stowed configuration to deployed configuration of the system depicted in 820 may be achieved with a mechanized system for controlled extension, retraction, or relative orientation.

In one example, the deployed concentrator structure has a fixed orientation with respect to the photovoltaic energy conversion system, and the entire structure's orientation with respect to the sun must be controlled, for instance with the photovoltaic surface facing away from the sun, with the reflective surface of the concentrator facing toward the sun. In one example, control of the relative orientation of the concentrator and PV with respect to the Sun is performed with active or passive feedback control involving light-sensing or heat-sensing components. In one example, the concentration factor of a given low specific mass space power system may be altered by varying the distance of the concentrator with respect to the PV system, effectively focusing or defocusing the filtered light. In one example, the concentration factor of a given low specific mass space power system may be altered by varying the shape, geometry, or relative orientation of the concentrator with respect to the PV cells by active or passive means. In one example, the sun-facing side of the photovoltaic surface is mirrored, i.e., coated with a thin-film reflective surface, for instance aluminum, silver, another metallic, or another highly reflective film, to reflect the full solar spectrum and to limit the total absorbed solar energy. In another example, a mirrored structure on the sun-side of the photovoltaics directs sunlight toward the concentrator surface to be filtered, reflected, and focused on the energy conversion side of the photovoltaics. In one example, the energy conversion side of the photovoltaics includes mirrored structures to guide filtered but misdirected sunlight onto the energy conversion area of the photovoltaics. In one example, the mirrored structures double as radiators for the PV system.

In one example, the low specific mass space power system achieves low specific mass through a combination of:
Concentrator surface design—enables a common low areal mass density structure to serve three functions: optical filtering, concentration of filtered sunlight onto PV cells, and rejection of other solar wavelengths via passive radiation.
High PV efficiency—uses narrowband illumination of spectrally-matched PV junctions, with concentration intensities that may exceed local broadband sunlight intensity.
Design—uses simple component technologies including, for example, solar sail-like deployable structures, optical filter coating common in the optics and physics communities, and photovoltaic technology.

In one example, the low specific mass space power system includes a process by which components including solar sail materials, thin-film optical coating technology or metamaterials, thin-film lenses, spacecraft deployable structures and photovoltaic cells may be combined, relying on the concentrator surface to spectrally filter and concentrate sunlight onto an associated and frequency-matched PV cells, while removing excess heat passively to enable low specific mass space power systems. In one example, the methods of the low specific mass space power system may be applied to space missions as a power unit for electric propulsion systems or for more generalized space mission power systems for use on transportation or surface platforms.

In one example, the low specific mass space power system may be used for on-Earth, near-Earth and cis-lunar missions as well as for Mars and deep space missions. The system is scalable and based on simple component technologies. For example, transformative human and robotic missions may be achievable with the low specific mass space power system. Such a system may optimize optical filter reflection coefficients, beam steering, areal mass density capabilities of deployable structures for the concentrator, PV efficiency and PV specific mass when illuminated by narrowband radiation.

In one example, rapid interplanetary transport from Earth to Mars is one exemplary usage of the low specific mass space power system. While electric propulsion thrusters are used today with existing power supplies for robotic missions, and while there are some low specific mass thruster examples that have been developed or are currently in development, there are currently no power sources with sufficiently low specific mass to enable rapid interplanetary transfers with shorter travel times than traditional chemical or nuclear thermal propulsion systems, for example, among other transformative applications of a combined space power and propulsion system with low specific mass. Another example application includes the application of low specific mass power and propulsion systems for high payload mass fraction deliveries in Earth orbit and beyond. Other example applications of a low specific mass space power system include operations of infrastructure elements or instruments on surface or transporting platforms like in-situ resource utilization plants on the lunar surface, Martian surface, or on other bodies in our Solar System, or for terrestrial power systems on Earth.

FIG. 9 illustrates an example 900 of requirements of the combined power and propulsion system specific mass as a function of the transfer time from Earth orbit to Mars orbit. The curves shown in 910 and 920 of FIG. 9 are based on characteristic lambda, λ, values for rapid trajectories presented in Berend (2012) and Melbourne (1961), where λ is the integral of the square of the thrust acceleration over the thrust interval. In FIG. 9, a propulsion system efficiency η^{th} is assumed to be 0.8 and a tank structural mass fraction k is assumed to be 0.05, with payload to initial mass fraction mₚₗ/m₀ as a parameter. The ordinate of the graphs shows the combined power and propulsion system specific mass αₚₚ in units of kg/kW. In one example, a space platform's combined power and propulsion system specific mass αₚₚ includes specific mass α contributions from the power generation system, the power management and distribution system, and the propulsion system.

FIGS. 10a and 10b illustrate example graphs 1010, 1020, 1030 of specific mass a sensitivity for a low specific mass space power system for use on, near, or far from Earth, for example in Earth orbit or at the Moon, near Mars, or near Jupiter. In one example, the combined specific mass α for the low specific mass space power system is composed of the sum of the PV system specific mass α_{PV} and the concentrator system specific mass α_{conc}. In one aspect, the example graphs 1010, 1020, 1030 depict sensitivity for specific masses apv and α_{conc}, and combined α_{PV}+α_{conc}, respectively, as they pertain to a low specific mass space power system operating at example distances of 1.0 AU, 1.5 AU, and 5.2 AU (astronomical units) from the Sun. Local sunlight intensity is assumed to be 1361 W/m² at 1.0 AU, 586.8 W/m² at 1.5 AU, and 50.3 W/m² at 5.2 AU. As illustrated, an example for the specific mass sensitivity for the PV system is plotted in 1010 as a function of PV efficiency η_{PV} (in %), filtered light concentration intensity (in kW/m²), and PV architecture (standard PV or thin-film PV). In one example, the PV specific mass apv does not depend directly on the operational distance from the Sun, but only on the incident intensity of concentrated, filtered light directed by the concentrator system. An example for the specific mass sensitivity for the concentrator system is plotted in 1020 as a function of areal mass density (in g/m²) and combined concentrator and PV system efficiency (in %). In one example, the concentrator specific mass α_{conc} depends on the local sunlight intensity, since the same configuration may produce more concentrated filtered sunlight power with higher incident sunlight intensity. An example for the specific mass sensitivity is plotted in 1030 for the combined PV system and concentrator system as a function of areal mass density (in g/m²) and filtered light concentration factor. Concentration factors of 10×, 25×, 50×, and 100× are shown along with the baseline example of no filtered concentration. An example concentration factor of 10× corresponds to a low mass specific space power system featuring an effective concentrator area that is 10× the effective area of photovoltaic cells in the PV system. In one example, the effective concentrator system area is the area of sunlight filtered and concentrated when measured in a plane normal to the sunlight incidence, and the effective PV system area is the collective photovoltaic cell area exposed to filtered light.

The graph 1010 shows the PV power conversion system specific mass assuming either 5 kW/m² or 10 kW/m² concentrated filtered sunlight provided by the concentrator. In this example, the PV system is assumed to have a specific mass baseline of 6 kg/kW for standard photovoltaic cells and 0.6 kg/kW for thin-film photovoltaic cells, assuming 30% PV conversion efficiency η_{PV} for operations at 1 AU with unfiltered, un-concentrated sunlight. The three graphs in 1020 show an example for concentrator system specific mass α_{conc} dependency on the combined areal mass density of the concentrator system, which includes surface, structural and control constituents. The three graphs in 1020 correspond to operations at 1.0 AU (graph 1020A), 1.5 AU (graph 1020B), and 5.2 AU (graph 1020C) from the Sun, corresponding to: operations on or near Earth or the Moon; operations on or near Mars; and operations in the vicinity of Jupiter, respectively. In 1020, the sensitivity of concentrator system specific mass α_{conc} to combined concentrator and PV system efficiency η_{conc}η_{PV} is depicted by varying the combined efficiency η_{conc}η_{PV} as well as the concentrator system areal mass density. In one example, the concentrator efficiency η_{conc} is the product of optical filter power fraction ηₒₚₜ (fraction of solar power filtered by the surface) and the steering efficiency ηₛₜₑₑᵣ (fraction of filtered power that is properly steered onto the PV cells). The three graphs in 1030 show an example for the sensitivity of combined PV system and concentrator system specific mass α_{PV}+α_{conc} as a function of concentrator system areal mass density and filtered light concentration factor. In 1030, three graphs depict an example low specific mass space power system with ηₒₚₜ=0.2, ηₛₜₑₑᵣ=0.85, and η_{PV}=0.45 corresponding to a combined efficiency η_{conc}η_{PV}=0.077. The three graphs in 1030 correspond to operational distances from the Sun of 1.0 AU (graph 1030A), 1.5 AU (graph 1030B), and 5.2 AU (graph 1030C). A horizontal gray dashed line in each of the three graphs in 1030 depicts the specific mass of a standard PV power system without concentration or sunlight filtering, assuming the use of a PV system that operates with η_{PV}=0.3 when exposed to unfiltered, unconcentrated sunlight, and which has a specific mass of 6 kg/kW when operating at 1.0 AU from the Sun. The black lines with varying thickness in the plots 1030 depict the combined specific mass α_{PV}+α_{conc} of examples for low specific mass space power system as a function of concentrator system areal mass density and filtered light concentration factor. The concentration factor is depicted with the thickness of the line, and is noted in the legend of 1030. In one example, the filtered light concentration factor is the ratio of the effective concentrator system area (the area of sunlight filtered and concentrated when measured in a plane normal to the sunlight incidence) to the effective PV system area (the collective photovoltaic cell area exposed to filtered light).

In one example, the low specific mass space power system specific mass, α, depends, in part, on the sum of the concentrator specific mass, α_{conc}, and the PV system specific mass, α_{PV}. For example, a standard PV system, i.e. not a thin-film PV system, may have a specific mass of 6 kg/kW at 1.0 AU with a PV efficiency of 30% assuming unfiltered and un-concentrated sunlight. The same reference PV system has, for example, a specific mass of 14 kg/kW at 1.5 AU assuming 30% PV efficiency when illuminated by unfiltered and un-concentrated sunlight. If a PV system with these properties were to be included in a low specific mass space power system near or far from Earth or the Moon, and the concentrator system illuminates the PV system by concentrated filtered and concentrated sunlight, a higher PV conversion efficiency is expected as well as a higher electrical power output from the PV system. For example, a PV system illuminated by 10 kW/m² filtered and concentrated sunlight may have a PV efficiency of η_{PV}=45%. This example corresponds to a PV specific mass of 0.54 kg/kW. This example is depicted as a star in 1010. An example concentrator with areal mass density of 20 g/m² operating with combined concentrator and PV system efficiency η_{conc}η_{PV}=7.5% corresponds to a concentrator specific mass of 0.20 kg/kW, 0.45 kg/kW, and 5.3 kg/kW for operations at a distance from the Sun of 1.0 AU, 1.5 AU, and 5.2 AU, respectively. These example concentrator specific masses are shown with stars in each of the three graphs in 1020 for operations at a distance from the Sun of 1.0 AU, 1.5 AU, and 5.2 AU, respectively. When the PV and concentrator specific masses are combined for an operational environment and concentrated filtered light intensity, the total estimated specific mass α of the low specific mass space power system can be calculated for an example. For a filtered light concentration intensity at the PV system of 10 kW/m², the low specific mass space power system specific mass for operations at 1.0 AU from the Sun (on or near Earth or the Moon), is α=α_{PV}+α_{conc}=0.54 kg/kW+0.20 kg/kW=0.74 kg/kW. At 1.5 AU from the Sun (on or near Mars), α=α_{PV}+α_{conc}=0.54 kg/kW+0.45 kg/kW=0.99 kg/kW. At 5.2 AU from the Sun (on or near Jupiter), α=α_{PV}+α_{conc}=0.54 kg/kW+5.3 kg/kW=5.84 kg/kW. The low specific mass space power system described in these examples may be used, for example, as a space power system for orbiting spacecraft or surface elements on or near Earth, the Moon, asteroids or comets, on or near Mars, or elsewhere in space. In one example for calculations involving combined concentrator and PV specific mass, the concentration factor is kept fixed for different operational environments. The graphs of 1030 depict the combined specific mass of low specific mass space power system examples operating at 1.0 AU, 1.5 AU, and 5.2 AU, showing that concentrator systems with areal mass densities less than 400 g/m² and concentration factors of 10× correspond to higher specific power and lower specific mass than the standard PV power system without concentration or filtering. Operating the same system with higher concentration factors reduces the specific mass of the low specific mass system further as indicated by the narrower plot lines in 1030, as indicated in the figure legend. In the graphs of 1030, the photovoltaic conversion efficiency with filtered light is assumed to be fixed at η_{PV}=0.45, but there may be other examples where photovoltaic efficiency is driven by concentration factor.

When the low specific mass space power system is used in conjunction with an electric propulsion system, overall power and propulsion system performance for example missions may be assessed. By using the rocket equation and interplanetary trajectory characteristics from the literature, the space platform capabilities defined for a given specific mass αₚₚ may be analyzed. FIG. 11a and FIG. 11b illustrate example mission profiles 1100, 1150, 1160 corresponding to an example mission from Earth to Mars (1100) and an example satellite orbit transfer from low Earth orbit (LEO) to geosynchronous orbit (GEO) (1150 and 1160). The example mission profiles 1100 are for various combined power and propulsion system specific mass αₚₚ values for a human or robotic mission to Mars beginning with an initial mass in low Earth orbit (IMLEO) of 250 metric tons. Given a desired trip time and platform power and propulsion system specific mass αₚₚ, the plots indicate the power requirement and payload capacity afforded by a given mission. Different specific masses are distinguished by plot line thickness and the left vertical axis depicts payload mass capacity while the right vertical axis depicts electrical power required. Three candidate missions and space platform designs are shown in FIG. 11a with stars in 1100. The first two designs correspond to two mission options for the same 21 MW, αₚₚ=3 kg/kW space platform design. In the first mission option example, a 96-day transit delivers an estimated 84 metric ton payload to Mars, both shortening the trip time and reducing the IMLEO needed as compared with other current Earth to Mars transit options, while delivering a similar payload. The second mission option example trades payload mass for faster transit speed, delivering 25 metric tons to Mars in just 70 days. The shorter transit affords overall missions lasting fewer than six months, as compared with the multi-year missions otherwise required to accommodate relative orbits for missions including human missions going to Mars and returning to Earth. The third mission example corresponds to a 63 MW, αₚₚ=1 kg/kW space platform design. With higher power and lower specific mass, this example enables the delivery of the heavy payload 84 metric tons to Mars with a transit time of 66 days, providing the benefit of short mission times for large payloads.

Table 2 shows an example technology roadmap for raising technology readiness levels and improving component-level and system-level technologies, methods and operations to ensure the reliability and performance for high power and heavy payload missions, for example missions involving human passengers. Each row of Table 2 corresponds to a mission example enabled by a low specific mass solar power system, with the final three rows corresponding to the three identified missions of FIG. 11a. Included in this roadmap is a 10 kg satellite, for example a CubeSat, with incremental technology goals to demonstrate a high performance, low specific mass system with small power and propulsion systems before scaling to larger, more powerful, or lower specific mass systems. Table 2 shows a proposed roadmap for Mars exploration missions (1.52 AU from sun). All rows assume spectrally-filtered 10 kW/m² at the PV, corresponding to concentration factors ranging from 73× to 133×, and all rows but the last assume a standard PV architecture while the last row assumes a thin-film PV architecture. Low specific mass space power system specific mass a and combined power and propulsion system specific mass αₚₚ in Table 2 assume operations at 1.52 AU with the local sunlight intensity. The local sunlight intensity at 1.52 AU is estimated to be 587 W/m². In Table 2, the effective concentrator surface area is the area of sunlight filtered and concentrated when measured in a plane normal to the sunlight incidence, and the effective PV array surface area is the collective photovoltaic cell area exposed to filtered light.

TABLE 2

| | | | | | | | | | | | Power System |
|---|---|---|---|---|---|---|---|---|---|---|---|
| | | | | | | | | | | | α (kg/kW)/ |
| Mars | | | Propulsion System | | | | | Effective | | Concentrator | Power and |
| Roadmap | | | Efficiency ηₜₕ/ | | Effective | | ηₒₚₜ/ | Concentrator | | Areal Mass | Propulsion |
| Mission | | | Tank Structure | Pay load | PV Array | | ηₛₜₑₑᵣ/ | Surface | | Density | System αₚₚ |
| Description | Power | | Fraction k | Mass/IMLEO | Surface Area | | η_{PV} | Area | | (g/m²) | (kg/kW) |
| CubeSat | 0.259 | kW | 0.6/0.1 | 4.31 kg/10 kg | 0.065 | m² | 0.15/ | 8.67 | m² | 71.5 | 3.0/9.0 |
| mission | | | | | | | 0.85/ | | | | |
| (180 day | | | | | | | 0.40 | | | | |
| transit) | | | | | | | | | | | |
| Robotic | 4.46 | kW | 0.7/0.1 | 27.4 kg/100 kg | 0.99 | m² | 0.18/ | 104 | m² | 62.0 | 2.0/6.0 |
| mission | | | | | | | 0.90/ | | | | |
| (light 120 | | | | | | | 0.45 | | | | |
| day transit) | | | | | | | | | | | |
| Robotic | 42.9 | kW | 0.8/0.05 | 146 kg/500 kg | 9.53 | m² | 0.18/ | 1,000 | m² | 19.5 | 1.0/3.0 |
| mission | | | | | | | 0.90/ | | | | |
| (light 90 | | | | | | | 0.45 | | | | |
| day transit) | | | | | | | | | | | |
| Robotic | 4.29 | MW | | 14,600 kg/50,000 kg | 2,220 | m² | | 0.273 | km² | | |
| mission | | | | | | | | | | | |
| (heavy 90 | | | | | | | | | | | |
| day transit) | | | | | | | | | | | |
| Human | 20.9 | MW | | 83,900 kg/250,000 kg | 4,640 | m² | | 0.488 | km² | | |
| mission | | | | | | | | | | | |
| (96 day | | | | | | | | | | | |
| transit) | | | | | | | | | | | |
| Human | 20.6 | MW | | 25,400 kg/250,000 kg | 4,580 | m² | | 0.482 | km² | | |
| mission | | | | | | | | | | | |
| (70 day | | | | | | | | | | | |
| transit) | | | | | | | | | | | |
| Human | 65.5 | MW | 0.8/0.05 | 83,900 kg/250,000 kg | 13,100 | m² | 0.26/ | 0.955 | km² | 19.5 | 0.3/1.0 |
| mission | | | | | | | 0.90/ | | | | |
| (66 day | | | | | | | 0.50 | | | | |
| transit) | | | | | | | | | | | |

Based on these analyses for examples of low specific mass space power systems, rapid human and robotic mission transits to Mars may be feasible in the near future with transit times less than half of those currently proposed and with less initial mass required in low Earth orbit. Less IMLEO reduces mission costs and complexity, and shorter transit times, or higher payload fractions, increase the utility of missions, and may also reduce the overall mission time, further reducing mission complexity and cost.

In addition to an application to fast transits to Mars, a broad set of applications for the low specific mass space power system exists on, near, and far from Earth or the Moon for electrically powered applications, for example for applications including solar power systems. For example, a low specific mass space power system may be readily applied to Earth-based systems on the ground, at sea, and in the air, or to space missions in Earth orbit, cis-lunar orbit, on or near the Moon, on or near Mars, and elsewhere in the Solar System or beyond. In one example, surface-based operations would benefit from low specific mass space power systems to perform the following example functions: mine and process water for human consumption or other use; mine and process fuel including hydrogen, oxygen, methane, or other chemicals for use with robotic or human vehicles, for example for missions from the surface to orbiting platforms or transfer vehicles; mine and process regolith or local materials for consumables or building materials; or other in-situ resource utilization functions. Many in-situ resource utilization functions require high power, and delivering power sources to the lunar surface, the Martian surface, or to other bodies in our Solar System can be prohibitively expensive, providing an additional motivation to reduce the specific mass of power systems to reduce launch costs to support these surface missions.

FIG. 11b depicts example mission profiles in 1150 and 1160 for a LEO to GEO transfer using a solar electric propulsion system with an assumed specific impulse of 1832 seconds and propulsion system efficiency of ηₜₕ=0.6. LEO to GEO transfers with solar electric propulsion allow for mass and cost savings for missions by reducing changes in velocity needed from the launch vehicle to deliver assets to transfer orbits or their final GEO orbits, reducing initial launch mass and cost. Higher payload fractions for orbital transfers allow for greater masses to be transferred to final mission orbits, increasing mission utility. Faster orbital transfers increase mission utility by allowing nominal operations at the final orbit to begin sooner, for example in the case of a communications satellite. In one example, the combined propulsion and power system specific mass αₚₚ is composed of the sum of propulsion system specific mass, power management and distribution system specific mass, and power system specific mass. FIG. 11b 1150 depicts mission profiles for an example spacecraft with a fixed propulsion system specific mass and power management and distribution system specific mass, combined to total 17.5 kg/kW. Payload mass fractions as a function of LEO to GEO transfer time and as a function of power system specific mass are depicted in FIG. 11b 1150. A baseline power system example with a specific mass α=7.7 kg/kW (specific power of 130 W/kg) is used to calculate a payload fraction delivered for a standard LEO to GEO transfer in 222 days. A gray star in FIG. 11b 1150 depicts this baseline example. Examples of LEO to GEO transfers of the same payload fraction enabled by a low specific mass space power system are depicted with black stars in FIG. 11b 1150. For example, spacecraft with low specific mass space power system examples with specific mass α=5 kg/kW, α=3 kg/kW, and α=1 kg/kW deliver the same LEO to GEO payload in 198 days, 181 days, and 163 days, respectively. FIG. 11b 1160 depicts mission profiles for an example spacecraft with a lower specific mass propulsion and power management and distribution system. In FIG. 11b 1160, the fixed propulsion system specific mass and power management and distribution system specific mass corresponds to a combined total of 6.0 kg/kW. Payload mass fractions as a function of LEO to GEO transfer time and as a function of power system specific mass are depicted in FIG. 11b 1160. A baseline power system example with a specific mass α=7.7 kg/kW (specific power of 130 W/kg) is used to calculate a payload fraction delivered for a standard LEO to GEO transfer in 222 days. A gray star in FIG. 11b 1160 depicts this baseline example. Examples of LEO to GEO transfers of the same payload fraction enabled by a low specific mass space power system are depicted with black stars in FIG. 11b 1160. For example, spacecraft with an example of the low specific mass space power system with specific mass α=5 kg/kW, α=3 kg/kW, and α=1 kg/kW deliver the same LEO to GEO payload in 178 days, 146 days, and 113 days, respectively.

Table 3 depicts examples of the low specific mass space power system as applied to operations near Saturn, Uranus, Neptune and Pluto. These examples are compared with the general purpose heat source radioisotope thermal generator (GPHS-RTG), a space power system currently used for deep space missions where sunlight intensity is low. A single GPHS-RTG unit provides roughly 300 W and has a mass of 56.4 kg. For example, the Cassini mission to Saturn used three GPHS-RTG units with a collective mass of roughly 169.2 kg for production of 889 W at beginning of life (BOL). A variety of low specific mass space power system examples are considered that produce the same power as the GPHS-RTG, but with reduced mass. Alternatively, for the same mass as the GPHS-RTG, a low specific mass space power system could provide deep space exploration platforms with higher power to enable more valuable science returns and higher utility missions.

Table 3 shows power system comparisons for deep space exploration missions. For missions to Saturn, operations are assumed to occur at 9.54 AU from the Sun, where the local sunlight intensity is estimated to be 14.96 W/m². Operations at Uranus are assumed to occur at 19.18 AU, with a local sunlight intensity of 3.70 W/m². Operations at Neptune are assumed to occur at 30.06 AU, with a local sunlight intensity of 1.51 W/m². Operations at Pluto are assumed to occur at Pluto's average orbiting distance of 39.44 AU, with a local sunlight intensity of 0.87 W/m². In Table 3, low specific mass (low-α) solar power system calculations assume examples with a filtered light concentration factor of 100×, and with ηₒₚₜ=0.2, .ηₛₜₑₑᵣ=0.85, and η_{PV}=0.45. The first two rows in Table 3 list examples for Saturn, comparing low specific mass space power system mass against the mass of three GPHS-RTG units (first row) and against the mass of one GPHS-RTG unit (second row). Examples of a low specific mass space power system are shown with concentrator areal mass densities ranging from 20 g/m² to 100 g/m². In each case, the low specific mass space power system example provides the same amount of power as the GPHS-RTG system with less mass allocated to the power system. The last rows of Table 3 depict the power delivered to missions at Uranus, Neptune, and Pluto for a single example of the low specific mass space power system of mass 15.7 kg, corresponding to a PV array area of 3.53 m², effective concentrator area of 353 m², and concentrator areal mass density of 20 g/m². No GPHS-RTG space power system mass is used for comparison in this case, since these examples correspond to delivered power levels lower than the minimum GPHS-RTG power, and would be applicable, for example, to systems that required power units with lower mass than the GPHS-RTG.

TABLE 3

| | | PV | Effective | Concentrator | | GPHS-RTG | |
|---|---|---|---|---|---|---|---|
| | BOL | Array | Concentrator | Areal Mass | Low-α Space | Space Power | |
| Mission | Power | Area | Surface Area | Density | Power System | System Mass | |
| Location | (W) | (m²) | (m²) | (g/m²) | Mass (kg) | (kg) | |
| Saturn | 889 | 7.77 | 777 | 20 | 34.6 | 169.2 | (3 units) |
| | | | | 50 | 57.9 | | |
| | | | | 100 | 96.7 | | |
| Saturn | 300 | 2.62 | 262 | 20 | 11.7 | 56.4 | (1 unit) |
| | | | | 50 | 19.5 | | |
| | | | | 100 | 32.6 | | |
| Uranus | 100 | 3.53 | 353 | 20 | 15.7 | N/A | |
| Neptune | 40.7 | | | | | | |
| Pluto | 23.7 | | | | | | |

The example of the 15.7 kg low specific mass space power system described in the final row of Table 3, which features a PV array area of 3.53 m², effective concentrator area of 353 m², and concentrator areal mass density of 20 g/m² is considered in one example for use in other mission contexts. Assuming a filtered light concentration factor of 100× and ηₒₚₜ=0.2, . ηₛₜₑₑᵣ=0.85, and η_{PV}=0.45, example missions are considered elsewhere in the Solar System. For example, with this low specific mass space power system, 404 W can be generated at Saturn (at 9.54 AU) with a filtered, concentrated intensity of 254 W/m², 1.36 kW at Jupiter (at 5.20 AU) with a filtered, concentrated intensity of 855 W/m², 15.9 kW at Mars (at 1.52 AU) with a filtered, concentrated intensity of 9.97 kW/m², and 36.8 kW at Earth or the Moon (at 1 AU) with a filtered, concentrated intensity of 23.1 kW/m². Given the high intensity of filtered, concentrated light at 1 AU of this example system, another example involves the use of a smaller concentration factor to reduce the thermal dissipation requirements for the PV system. For example, the same example low specific mass space power system (PV array area of 3.53 m², a concentrator areal mass density of 20 g/m², with ηₒₚₜ=0.2, . ηₛₜₑₑᵣ=0.85, and η_{PV}=0.45) can be considered for use with a concentration factor of 43×, corresponding to an effective concentrator area of 152 m². In this example, an estimated 15.8 kW could be produced on or near the Earth or Moon (at 1 AU) with a filtered, concentrated intensity of 9.95 kW/m².

FIG. 12 illustrates a flow diagram 1200 for generating solar power. In block 1210, filter a light to generate a filtered light and a rejected light. In block 1220, concentrate the filtered light to a plurality of photovoltaic (PV) cells. And, in block 1230, passively radiate the rejected light. In one example, the filtered light is concentrated towards the plurality of photovoltaic (PV) cells. In one example, the concentrating step includes reflecting the filtered light. In one example, the concentrating step includes transmitting the filtered light. In one example, the passively radiating step includes transmitting the rejected light. In another example, the passively radiating step includes absorbing the rejected light. In another example, the passively radiating step includes reflecting the rejected light. In block 1240, generate solar power from the plurality of PV cells.

In one aspect, one or more of the steps for providing a low specific mass space power system may be executed by one or more processors which may include hardware, software, firmware, etc. The one or more processors, for example, may be used to execute software or firmware needed to perform the steps in the flow diagram of FIG. 12. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in a processing system, external to the processing system, or distributed across multiple entities including the processing system. The computer-readable medium may be embodied in a computer program product. By way of example, a computer program product may include a computer-readable medium in packaging materials. The computer-readable medium may include software or firmware for providing a low specific mass space power system. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

What is claimed is:

1. An apparatus comprising:
a concentrator, wherein the concentrator includes an optical filter and wherein the optical filter includes a first characteristic of concentrating a filtered light and a second characteristic of passively radiating a rejected light;
a photovoltaic (PV) conversion system coupled to the concentrator, wherein the photovoltaic (PV) conversion system includes a plurality of photovoltaic (PV) cells, wherein a majority quantity of the plurality of photovoltaic (PV) cells is spectrally matched to the filtered light.

2. The apparatus of claim 1, wherein the optical filter includes a spectral window.

3. The apparatus of claim 2, wherein the single spectral window reflects or transmits the filtered light.

4. The apparatus of claim 3, wherein the single spectral window transmits, absorbs, or reflects the rejected light.

5. The apparatus of claim 4, wherein the optical filter is a reflectance/transmittance (R/T) filter.

6. The apparatus of claim 4, wherein the optical filter is a transmittance/absorbance (T/A) filter.

7. The apparatus of claim 4, wherein the optical filter is a transmittance/reflectance (T/R) filter.

8. The apparatus of claim 1, wherein the concentrator is a concave reflector (CR).

9. The apparatus of claim 1, wherein the concentrator is a light-channel (LC).

10. The apparatus of claim 1, wherein the concentrator comprises a low areal mass density deployable structure.

11. A method for solar power generation, the method comprising:
filtering a light to generate a filtered light and a rejected light;
concentrating the filtered light; and
passively radiating the rejected light.

12. The method of claim 11, further comprising concentrating the filtered light to a plurality of photovoltaic (PV) cells.

13. The method of claim 12, wherein the concentrating includes reflecting the filtered light.

14. The method of claim 13, wherein the passively radiating includes transmitting the rejected light.

15. The method of claim 13, wherein the passively radiating includes absorbing the rejected light.

16. The method of claim 12, further comprising generating solar power using the plurality of photovoltaic (PV) cells.
